(19) United States
(12) Patent Application Publication
(10) Pub. No.: US 2010/0250830 A1
(43) Pub. Date: Sep. 30, 2010

(54) SYSTEM, METHOD, AND COMPUTER PROGRAM PRODUCT FOR HARDENING DATA STORED ON A SOLID STATE DISK

(76) Inventor: Ross John Stenfort, Los Altos, CA (US)

Correspondence Address: SANDFORCE, INC.;Attention: Earl Cohen, 12950 Saratoga Ave, Saratoga, CA, 95070-4658, US

(21) Appl. No.: 12/413,329

(22) Filed: Mar. 27, 2009

(51) Int. Cl. G06F 12/00; G11C 5/14; G06F 12/02; G06F 12/08

(52) U.S. Cl. 711/103; 365/228; 711/135; 711/E12.001; 713/324; 711/E12.008; 711/E12.022

(57) ABSTRACT

A system, method, and computer program product are provided for hardening data stored on a solid state disk. In operation, it is determined whether a solid state disk is to be powered off. Furthermore, data stored on the solid state disk is hardened if it is determined that the solid state disk is to be powered off.

### FIELD OF THE INVENTION

The present invention relates to solid state disks (SSDs), and more particularly to hardening data stored on such solid state disks.

### BACKGROUND

Typically, solid state disks (SSDs) have super capacitors or batteries. The super capacitors and batteries function such that when power is removed they are able to provide power to allow all volatile data from the solid state disk to be flushed and place the data into flash memory. In this way the data may be flushed without any loss.

In general, super capacitors and batteries have a relatively large cost. Furthermore, in some cases, the super capacitors and batteries are prone to failure. There is thus a need for addressing these and/or other issues associated with the prior art.

### SUMMARY

A system, method, and computer program product are provided for hardening data stored on a solid state disk. In operation, it is determined whether a solid state disk is to be powered off. Furthermore, data stored on the solid state disk is hardened if it is determined that the solid state disk is to be powered off.

### BRIEF DESCRIPTION OF THE DRAWINGS

FIG. 1 shows a method for hardening data stored on a solid state disk, in accordance with one embodiment.

FIG. 2 shows a system for hardening data stored on a solid state disk, in accordance with one embodiment.

FIG. 3 shows a system for hardening data stored on a solid state disk, in accordance with another embodiment.

FIG. 4 shows a method for hardening data stored on a solid state disk, in accordance with another embodiment.

FIG. 5 illustrates an exemplary system in which the various architecture and/or functionality of the various previous embodiments may be implemented.

### DETAILED DESCRIPTION

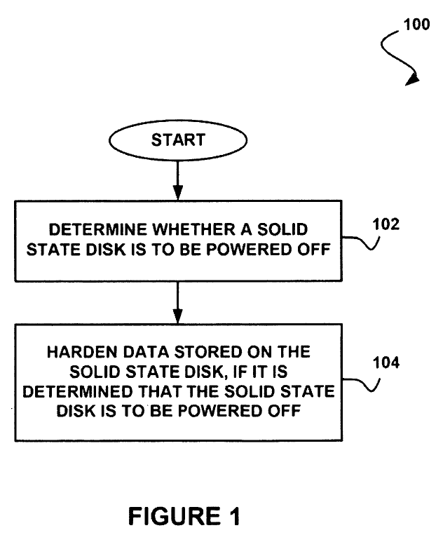

FIG. 1 shows a method 100 for hardening data stored on a solid state disk, in accordance with one embodiment. In operation, it is determined whether a solid state disk is to be powered off. See operation 102. It may be determined that the solid state disk is to be powered off based on different criteria.

For example, in one embodiment, it may be determined that the solid state disk is to be powered off based on receiving a power off command. In another embodiment, it may be determined that the solid state disk is to be powered off based on receiving a cycle power command. In yet another embodiment, it may be determined that the solid state disk is to be powered off based on receiving an error signal.

If it is determined that the solid state disk is to be powered off, data stored on the solid state disk is hardened. See operation 104. In the context of the present description, hardening data refers to any technique of writing data in cache or volatile memory to non-volatile memory such as flash memory.

In one embodiment, hardening the data stored on the solid state disk may include issuing a command to harden the data. In this case, the command to harden the data may be issued to the solid state disk or a memory controller associated therewith. The command to harden the data may include any command to harden the data.

For example, in one embodiment, the command to harden the data may include a flush cache command. In another embodiment, the command to harden the data may include a sleep command. In still another embodiment, the command to harden the data may include a standby immediate command.

In one embodiment, it may be determined that the solid state disk is to be powered off as part of power cycling. In this case, the power cycling may be a result of an error recovery. Thus, a device (e.g. a bridge, a memory controller, etc.) may issue the command to harden the data. In one embodiment, after the device issues the command to harden the data, the data may be hardened and the solid state disk may be power cycled.

More illustrative information will now be set forth regarding various optional architectures and features with which the foregoing framework may or may not be implemented, per the desires of the user. It should be strongly noted that the following information is set forth for illustrative purposes and should not be construed as limiting in any manner. Any of the following features may be optionally incorporated with or without the exclusion of other features described.

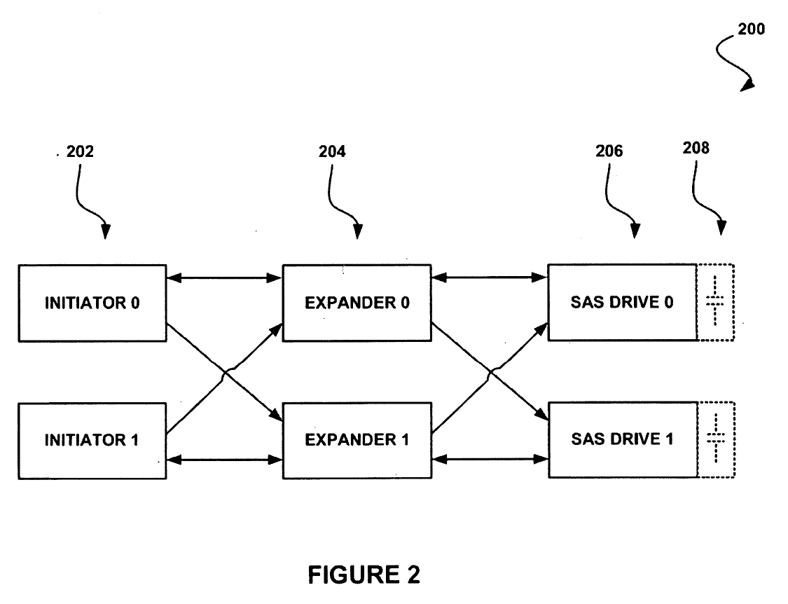

FIG. 2 shows a system 200 for hardening data stored on a solid state disk, in accordance with one embodiment. As an option, the present system 200 may be implemented to carry out the method 100 of FIG. 1. Of course, however, the system 200 may be implemented in any desired environment. It should also be noted that the aforementioned definitions may apply during the present description.

As shown, the system 200 may include one or more initiators 202. The initiators 202 may be coupled to and in communication with one or more expanders 204. Additionally, the initiators 202 and the expanders 204 may be coupled to and in communication with one or more memory devices 206.

As shown further, the one or more memory devices 206 may include one or more super capacitors 208. It should be noted that, although the memory devices 206 are discussed in the context of including super capacitors 208, the super capacitors 208 may equally represent one or more batteries. It should also be noted that, in another embodiment, the super capacitors 208 may not be included with the memory devices 206. For example, in one embodiment, the memory devices 206 may function without the super capacitors 208 or batteries.

In one embodiment, the one or more memory devices 206 may include one or more Serial Attached SCSI (SAS) drives. In this case, the system 200 may operate as a Serial Attached SCSI (SAS) system with SAS drives. In various other embodiments, the one or more memory devices 206 may include any type of solid state disk.

In operation, it is determined whether at least one of the memory devices 206 is to be powered off. For example, in one embodiment, one of the initiators 202 may determine that the memory devices 206 are to be powered off. In another embodiment, a memory controller or a protocol chip associated with the memory devices 206 may determine that the memory devices 206 are to be powered off.

In one embodiment, the determination that the memory devices 206 are to be powered down may be based on the receipt and/or issuance of a power down command. In another embodiment, the determination that the memory devices 206 are to be powered down may be based on the receipt and/or issuance of a sleep command. In still another embodiment, the determination that the memory devices 206 are to be powered down may be based on the receipt and/or issuance of a standby immediate command.

If it is determined that the memory devices 206 are to be powered off, any data stored on the memory devices 206 may be hardened. It should be noted that any or all data stored on the memory devices 206 may be hardened. For example, the data that is hardened my include user data, protection data, or both user data and protection data.

In the context of the present description, protection data refers to any data stored in memory that is utilized to ensure the accuracy and/or validity of user data. In this case, user data refers to any data that is stored in the memory that is not protection data.

In one embodiment, the memory devices 206 may send information to the initiators 202. For example, the information may include a status indicating a last time the super capacitor 208 was tested. Additionally, the information may include results of a test of the super capacitor 208. In this case, the results may indicate a success or failure of the test of the super capacitor 208.

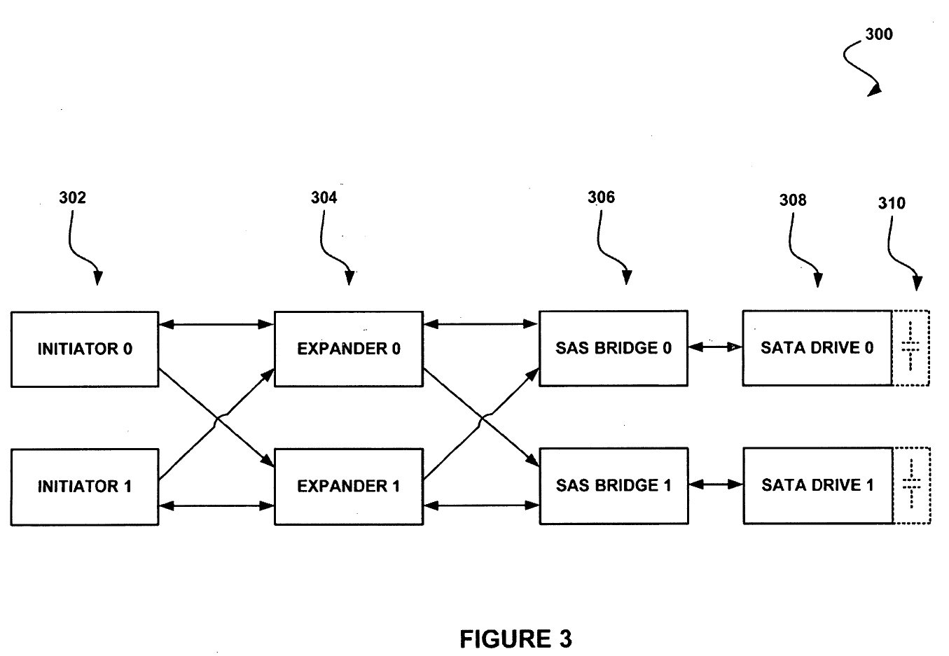

FIG. 3 shows a system 300 for hardening data stored on a solid state disk, in accordance with another embodiment. As an option, the present system 300 may be implemented in the context of the details of FIGS. 1-2. Of course, however, the system 300 may be implemented in any desired environment. Again, the aforementioned definitions may apply during the present description.

As shown, the system 300 may include one or more initiators 302. The initiators 302 may be coupled to and in communication with one or more expanders 304. Additionally, one or more bridges 306 may be positioned such that information transmitted from the initiators 302 and/or the expanders 304 is received by the one or more bridges 306 before being communicated to one or more memory devices 308.

As shown further, the memory devices 308 may include one or more super capacitors 310. It should be noted that, although the memory devices 308 are discussed in the context of including super capacitors 310, the super capacitors 310 may equally represent one or more batteries. It should be noted that, in another embodiment, the super capacitors 310 may not be included with the memory devices 308. For example, in one embodiment, the memory devices 308 may function without the super capacitors 310 or batteries.

In one embodiment, the one or more bridges 306 may include one or more Serial Attached SCSI (SAS) bridges. Additionally, in one embodiment, the one or more memory devices 308 may include one or more Serial ATA (SATA) drives. In this case, the system 300 may operate as SAS system with SAS bridges for converting Serial SCSI Protocol (SSP) information or Serial Management Protocol (SMP) information to SATA information.

In operation, one or more of the bridges 306 may determine whether at least one of the memory devices 308 is to be powered off. In one embodiment, the determination that the memory devices 308 are to be powered down may be based on the receipt and/or issuance of a power down command at or by the bridges 306.

In another embodiment, the determination that the memory devices 308 are to be powered down may be based on the receipt and/or issuance of a sleep command at or by the bridges 306. In still another embodiment, the determination that the memory devices 308 are to be powered down may be based on the receipt and/or issuance of a standby immediate command at or by the bridges 306.

It should be noted that the bridges 306 may receive and/or send a variety of information to and from the initiators 302 and the memory devices 308. For example, in one embodiment, the one or more of the bridges 306 may receive logical block address de-allocation information, such as a command to de-allocate at least a portion of the one or more memory devices 308. This de-allocation command may be in a first format associated with a first protocol, such as an SSP or SMP format.

One or more of the bridges 306 may then convert the de-allocation command in the SSP or SMP format to a second format associated with a second protocol, such as an ATA format associated with the one or more SATA drives 308. In one embodiment, converting the logical block address de-allocation information in the first format to the second format may include converting an SCSI UNMAP command to an ATA data set management command (e.g. using a TRIM setting, etc.). The drives 308 may then de-allocate data in response to the converted de-allocation command.

In another embodiment, power loss information may be received (e.g. by the bridges 306, etc.) in the first format associated with the first protocol. In this case, the power loss information in the first format may be converted to the second format associated with the second protocol. For example, the power loss information may include an SCSI power loss primitive (e.g. a NOTIFY primitive, etc.). Thus, converting the power loss information in the first format to the second format may include converting the SCSI power loss primitive into an ATA flush cache command.

Additionally, converting the power loss information in the first format to the second format may include converting a power loss primitive or a power loss command to a primitive or command for hardening data. In the context of the present description, hardening data refers to any technique of writing data in cache to memory such as flash memory. Accordingly, a power loss primitive or command may be received by the bridges 306 and may be converted to any command or primitive for hardening the stored data.

More information regarding converting the logical block address de-allocation status information and power loss information may be found in U.S. patent application Ser. No. ______, titled “SYSTEM, METHOD, AND COMPUTER PROGRAM PRODUCT FOR CONVERTING LOGICAL BLOCK ADDRESS DE-ALLOCATION INFORMATION IN A FIRST FORMAT TO A SECOND FORMAT,” filed on ______, which is incorporated by reference in its entirety.

If it is determined that the memory devices 308 are to be powered off, any data stored on the memory devices 308 may be hardened. It should be noted that any or all data stored on the memory devices 308 may be hardened. For example, the data that is hardened my include user data, protection data, or both user data and protection data.

In one embodiment, the memory devices 308 may send information to the bridges 306. For example, the information may include a status indicating a last time the super capacitor 310 was tested. Additionally, the information may include results of a test of the super capacitor 310. In this case, the results may indicate a success or failure of the test of the super capacitor 310.

The bridges 306 are not necessarily limited to receiving information. In one embodiment, the bridges 306 may also convert information being communicated from the memory devices 308. For example, in one embodiment, a de-allocation status may be sent from the memory devices 308. In various embodiments, this status may be in response to a query or another command sent to the memory devices 308.

More information regarding converting the logical block address de-allocation status information may be found in U.S. patent application Ser. No. ______, titled “SYSTEM, METHOD, AND COMPUTER PROGRAM PRODUCT FOR CONVERTING LOGICAL BLOCK ADDRESS DE-ALLOCATION INFORMATION IN A FIRST FORMAT TO A SECOND FORMAT,” filed on ______, which has been incorporated by reference in its entirety.

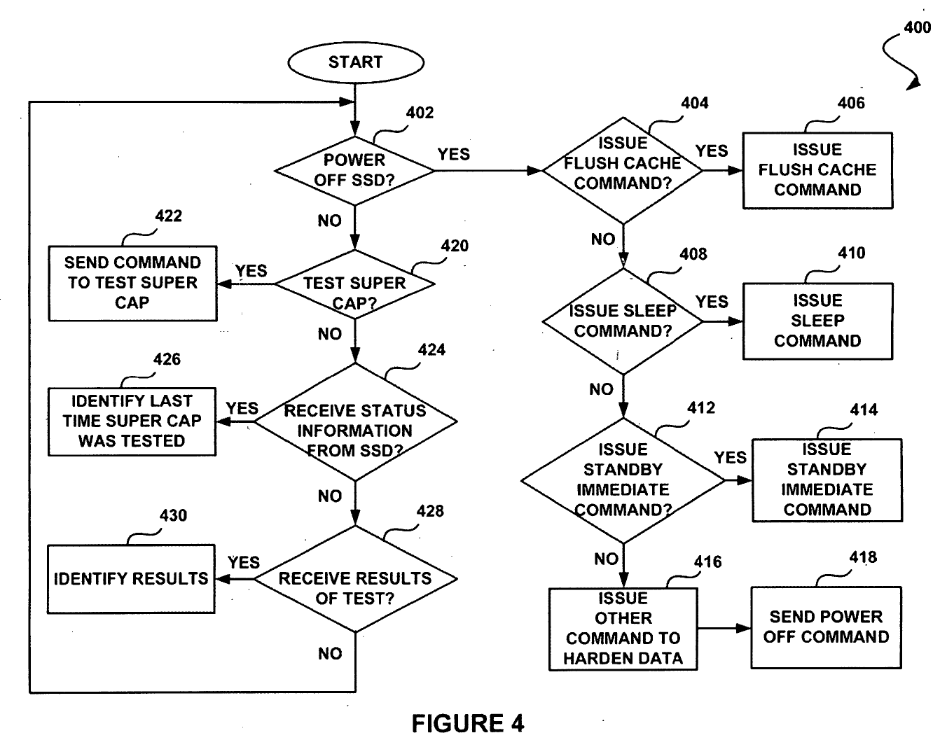

FIG. 4 shows a method 400 for hardening data stored on a solid state disk, in accordance with another embodiment. As an option, the present method 400 may be implemented in the context of the functionality and architecture of FIGS. 1-3. Of course, however, the method 400 may be carried out in any desired environment. Further, the aforementioned definitions may apply during the present description.

As shown, it is determined whether a command to power off a solid state disk is received. See operation 402. In one embodiment, it may be determined that the solid state disk is to be powered off as part of power cycling. For example, the power cycling may be a result of an error recovery.

If a command is received to power off the solid state disk, it is determined whether to issue a flush cache command. See operation 404. If it is determined to issue a flush cache command, the flush cache command is issued. See operation 406. In one embodiment, a bridge may issue the flush cache command.

It is further determined whether to issue a sleep command. See operation 408. If it is determined to issue a sleep command, the sleep command is issued. See operation 410. In one embodiment, a bridge may issue the sleep command.

Additionally, it is determined whether to issue a standby immediate command. See operation 412. If it is determined to issue a standby immediate command, the standby immediate command is issued. See operation 414. Again, in one embodiment, a bridge may issue the standby immediate command.

If it is determined that a flush cache command, a sleep command, and a standby immediate command are not to be issued, another data hardening command is issued before powering off the solid state disk. See operation 416. Once the data hardening command is issued, a power off or power cycle command is sent. See operation 418.

It should be noted that by issuing a command to harden data (e.g. a flush cache command, a sleep command, a standby immediate command, or some other command, etc.) before powering off, the solid state disk may be implemented without a super capacitor or battery. This may be implemented to increased reliability of the solid state disk.

In one embodiment, however, the solid state disk may include a super capacitor or battery. For example, a solid state disk may have a super capacitor or battery so that when power is removed the solid state disk may flush all the data out to flash without losing data. In this case, an initiator or bridge may send a command to a solid state disk to test the super capacitor or battery. Additionally, a solid state disk may return status about the last time the super capacitor or battery was tested.

Thus, in addition to determining whether a power off command is received for the solid state disk, in one embodiment, it may be determined whether to send a command to test one of a su per capacitor or battery associated with the solid state disk. See operation 420. If it is determined to test the super capacitor or battery, die command to test the super capacitor or battery associated with the solid state disk is sent. See operation 422.

In one embodiment, the command to test the super capacitor or battery associated with the solid state disk may be sent by an initiator. In another embodiment, the command to test the super capacitor or battery associated with the solid state disk may be sent by a bridge.

It may also be determined if any information is received from the solid state disk. The information may include any type of information. For example, in one embodiment, de-allocation status information may be received from the solid state device.

More information regarding sending and receiving de-allocation status information may be found in U.S. patent application Ser. No. ______, titled “SYSTEM, METHOD, AND COMPUTER PROGRAM PRODUCT FOR SENDING LOGICAL BLOCK ADDRESS DE-ALLOCATION STATUS INFORMATION,” filed on ______, which is incorporated by reference in its entirety.

Additionally, it may be determined if information including a status indicating a last time the super capacitor or battery associated with the solid state disk was tested is received. See operation 424. In this case, the solid state disk may send the status indicating the last time the super capacitor or battery associated with the solid state disk was tested.

Using this information, the last time the super capacitor or battery was tested may be identified. See operation 426. Based on this identification, it may further be determined that a test of the super capacitor or battery should initiated.

In addition to determining if a status of the super capacitor or battery was received, it may also be determined if results of a super capacitor or battery test are received. See operation 428. If results of the test are received, the results are identified. See operation 430.

In this case, the results of the test may indicate a success or failure of the test of the super capacitor or battery. Based on these results, it may be determined that another test of the super capacitor or battery should be initiated. In this way, the status of a super capacitor or battery may be determined and it may be determined whether to test the super capacitor or battery.

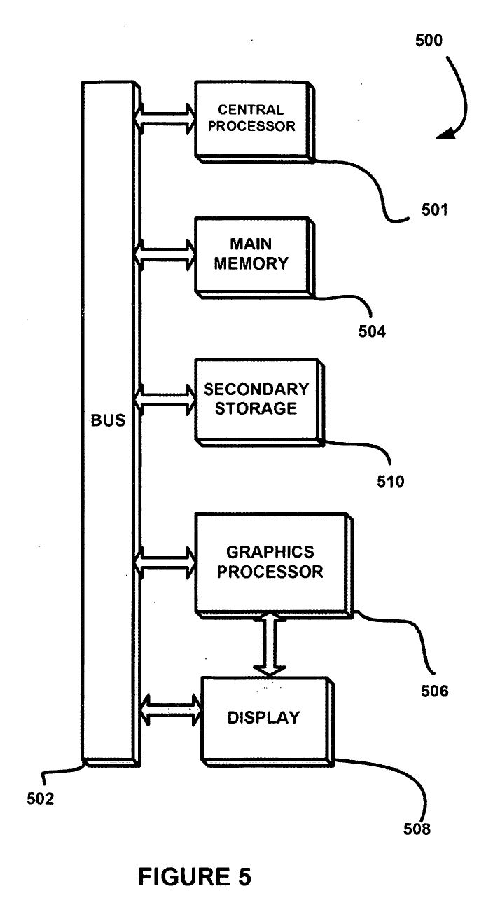

FIG. 5 illustrates an exemplary system 500 in which the various architecture and/or functionality of the various previous embodiments may be implemented. As shown, a system 500 is provided including at least one host processor 501 which is connected to a communication bus 502. The system 500 also includes a main memory 504. Control logic (software) and data are stored in the main memory 504 which may take the form of random access memory (RAM).

The system 500 also includes a graphics processor 506 and a display 508, i.e. a computer monitor. In one embodiment, the graphics processor 506 may include a plurality of shader modules, a rasterization module, etc. Each of the foregoing modules may even be situated on a single semiconductor platform to form a graphics processing unit (GPU).

In the present description, a single semiconductor platform may refer to a sole unitary semiconductor-based integrated circuit or chip. It should be noted that the term single semiconductor platform may also refer to multi-chip modules with increased connectivity which simulate on-chip operation, and make substantial improvements over utilizing a conventional central processing unit (CPU) and bus implementation. Of course, the various modules may also be situated separately or in various combinations of semiconductor platforms per the desires of the user.

The system 500 may also include a secondary storage 510. The secondary storage 510 includes, for example, a hard disk drive and/or a removable storage drive, representing a floppy disk drive, a magnetic tape drive, a compact disk drive, etc. The removable storage drive reads from and/or writes to a removable storage unit in a well known manner.

Computer programs, or computer control logic algorithms, may be stored in the main memory 504 and/or the secondary storage 510. Such computer programs, when executed, enable the system 500 to perform various functions. Memory 504, storage 510 and/or any other storage are possible examples of computer-readable media.

In one embodiment, the architecture and/or functionality of the various previous figures may be implemented in the context of the host processor 501, graphics processor 506, an integrated circuit (not shown) that is capable of at least a portion of the capabilities of both the host processor 501 and the graphics processor 506, a chipset (i.e. a group of integrated circuits designed to work and sold as a unit for performing related functions, etc.), and/or any other integrated circuit for that matter.

Still yet, the architecture and/or functionality of the various previous figures may be implemented in the context of a general computer system, a circuit board system, a game console system dedicated for entertainment purposes, an application-specific system, and/or any other desired system. For example, the system 500 may take the form of a desktop computer, lap-top computer, and/or any other type of logic. Still yet, the system 500 may take the form of various other devices including, but not limited to, a personal digital assistant (PDA) device, a mobile phone device, a television, etc.

Further, while not shown, the system 500 may be coupled to a network [e.g. a telecommunications network, local area network (LAN), wireless network, wide area network (WAN) such as the Internet, peer-to-peer network, cable network, etc.] for communication purposes.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A method, comprising:
determining whether a solid state disk is to be powered off; and
hardening data stored on the solid state disk, if it is determined that the solid state disk is to be powered off.

2. The method of claim 1, wherein hardening the data stored on the solid state disk includes issuing a command to harden the data.

3. The method of claim 2, wherein the command to harden the data includes a flush cache command.

4. The method of claim 2, wherein the command to harden the data includes a sleep command.

5. The method of claim 2, wherein the command to harden the data includes a standby immediate command.

6. The method of claim 2, wherein it is determined that the solid state disk is to be powered off as part of power cycling.

7. The method of claim 6, wherein the power cycling is a result of an error recovery.

8. The method of claim 7, wherein a bridge issues the command to harden the data.

9. The method of claim 8, further comprising performing the power cycling, after the bridge issues the command to harden the data.

10. The method of claim 1, further comprising sending a command to the solid state disk to test one of a super capacitor or battery associated with the solid state disk.

11. The method of claim 10, wherein the command to test the one of the super capacitor or battery associated with the solid state disk is sent by an initiator.

12. The method of claim 11, wherein the command to test the one of the super capacitor or battery associated with the solid state disk is sent by a bridge.

13. The method of claim 1, further comprising receiving information from the solid state disk.

14. The method of claim 13, wherein the information includes a status indicating a last time one of a super capacitor or battery associated with the solid state disk was tested.

15. The method of claim 14, wherein the solid state disk sends the status indicating the last time the one of the super capacitor or battery-associated with the solid state disk was tested.

16. The method of claim 13, wherein the information includes results of a test of one of a super capacitor or battery associated with the solid state disk.

17. The method of claim 14, wherein the results indicate a success or failure of the test of the super cap.

18. A computer program product embodied on a computer readable medium, comprising:
computer code for determining whether a solid state disk is to be powered off; and
computer code for hardening data stored on the solid state disk, if it is determined that the solid state disk is to be powered off.

19. An apparatus, comprising:
a device for determining whether a solid state disk is to be powered off and for hardening data stored on the solid state disk, if it is determined that the solid state disk is to be powered off.

20. The apparatus of claim 19, wherein the device includes a bridge.
